(19) United States
(12) Patent Application Publication
(10) Pub. No.: US 2022/0149782 A1
(43) Pub. Date: May 12, 2022

(54) EXCHANGER APPARATUS FOR GENERATING ELECTRICITY AND HEAT

(71) Applicant: NOVAPRECISIO S.R.L., MILANO (IT)

(72) Inventor: Francesco ZANINI, Bologna (IT)

(73) Assignee: NOVAPRECISIO S.R.L., MILANO (IT)

(21) Appl. No.: 17/438,901

(22) PCT Filed: Feb. 27, 2020
(86) PCT No.: PCT/IB2020/051677

§ 371 Date: Sep. 13, 2021

(30) Foreign Application Priority Data
Mar. 12, 2019 (IT) 102019000003611

(51) Int. Cl. H02S 40/44; F24H 9/1818; F24H 1/00; H01L 31/0328; H01L 31/0352; H01L 31/068

(52) U.S. Cl. CPC H02S 40/44; F24H 9/1818; F24H 1/0018; H01L 31/0328; H01L 35/32; H01L 31/068; F24H 2240/09; F24H 2240/08; F24H 2250/06; H01L 31/035272

(57) ABSTRACT

The present invention relates to an exchanger apparatus (1) for supplying electricity and heat, comprising a radiator element (2) able to irradiate energy as a function of an operating temperature thereof; an electronic device (3) designed to produce output electricity from the energy irradiated by the element, thereby dissipating heat; and a heat exchanger (4) designed to absorb the heat dissipated by the electronic device (3), thereby increasing the temperature of an output fluid.

### TECHNICAL FIELD

The present invention relates to an exchanger apparatus that is capable of generating electricity and heat simultaneously.

In greater detail, the invention relates to an apparatus that is specially designed to supply electricity and hot water for users of various kinds, for example industrial or domestic users.

### PRIOR ART

There are known cogeneration systems which are composed of a prime mover, for example an internal combustion engine or a turbine, an electric generator driven by the prime mover and heat exchangers to recover the heat dissipated by the system.

By virtue of this configuration, the known system is capable of supplying both heat and electricity to a user.

However, since the known cogeneration systems use components of a mechanical type, they suffer from intrinsic limits in so far as efficiency is concerned and are moreover subject to wear, which affects maintenance costs, as well as often having a negative impact on the environment.

### OBJECT OF THE INVENTION

The technical task at the basis of the present invention is thus to propose an exchanger apparatus capable of producing heat and electricity, while at the same time overcoming the limits of the prior art.

This task is fulfilled by the apparatus constructed in accordance with claim 1.

### BRIEF DESCRIPTION OF THE DRAWINGS

Additional features and advantages of the present invention will become more apparent from the approximate, and thus non-limiting, description of a preferred but non-exclusive embodiment of an exchanger apparatus according to the invention, as illustrated in the accompanying drawings, in which:

FIG. 1 represents an operating diagram of the apparatus of the invention;

FIG. 2 is a schematic representation of an essential module of the proposed apparatus; and

FIG. 3 is a schematic representation of a particular embodiment the invention.

### DETAILED DESCRIPTION OF PREFERRED EMBODIMENTS OF THE INVENTION

With reference to the appended figures, 1 denotes an exchanger apparatus according to the invention.

The proposed apparatus 1 is conceived to provide a user with both electricity and heat, without the use of any component of a mechanical nature.

The apparatus 1 of the invention includes first of all at least one radiator element 2, which, in general terms, is able to irradiate energy to the outside as a function of an operating temperature thereof.

In particular, the radiator element 2 is able to irradiate electromagnetic energy in the infrared region, i.e. at wavelengths comprised between 700 nm and 1 mm.

For example, the radiator element 2 can be an exchanger through which a hot working fluid flows; the working fluid preferably consists of diathermic oil or ethylene glycol or water.

Because of the temperature assumed by the passage of the hot fluid, the radiator element 2 emits electromagnetic radiation in the infrared field and heat.

Another important component of the invention is an electronic device 3 which produces output electricity from the irradiated energy received, thereby dissipating heat.

For example, the electronic device 3 in question can be a photovoltaic panel that receives the infrared radiation emitted by the radiator element 2 and transforms it into electricity.

In particular, the wavelengths at which the electronic device 3 functions are comprised between 700 nm and 1 mm, i.e. they fall in the infrared region. In this range of frequencies, in fact, a traditional photovoltaic panel would have yields close to 0.

The electronic device 3 is preferably made up of two doped N-type and P-type semiconductor materials, connected to each other by a copper blade. The geometric structure is such as to develop a quantum leap able to generate the production of electricity if irradiated by infrared radiation. The structure of the device 3 is formed by rectangles of equal dimensions over the whole surface of the N-type and P-type semiconductor.

The semiconductor used is a compound of bismuth and tellurium. Bismuth is a semiconductor that, when it is alloyed with antimony or selenium, is an efficient thermoelectric material for refrigeration or portable power generation.

The structure of the electronic device 3 is created with alternating P-type and N-type doping very similar to that of a traditional Peltier cell; however, its function is conceptually very different. Whereas in a Peltier cell, electric generation occurs through the Seebeck effect, i.e. through thermal conduction, and thus the transfer of heat from one face to another of the material, in the electronic device 3 of the present invention no heat transfer takes place.

In fact, the material produces electricity through infrared irradiation.

The efficiency is much higher compared to Seebeck generation, as it is close to the efficiency of a photovoltaic system, since no contact occurs between the electronic device 3 and the hot body of the radiator element 2. In this manner, one avoids thermal dispersion due to contact, as shown in the figure.

The photovoltaic panel 3 can be provided with an inverter to supply, as output, electricity to the network.

Alternatively, or in addition, the electronic device 3 can include at least one Peltier cell for transforming the heat received from the radiator element 2 into current.

Furthermore, the apparatus 1 proposed includes at least one heat exchanger 4 which is designed to absorb the heat dissipated by the electronic device 3 in producing current, thereby increasing the temperature of an output fluid, which is then supplied hot to the intended user.

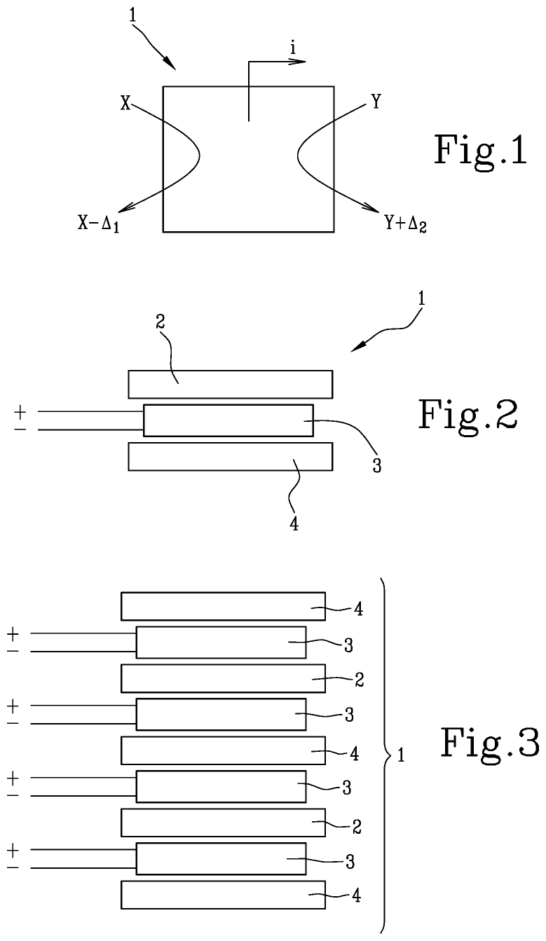

The operating principle is schematically shown in FIG. 1.

The apparatus 1 receives as input an energy X, from which it draws a part Δ₁, transforming it into electricity, thereby producing the current i and transferring a thermal energy equal to a Δ₂ (less than Δ₁) to the output initially provided with the energy Y.

As illustrated in FIGS. 2 and 3, a space or gap of between a few mm and a few cm is present between every layer 2, 3, 4 of the exchanger apparatus 1. In particular, the gap between the radiator element 2 and the electronic device 3 designed to produce electricity is comprised between 0.1 mm and 1 mm, so as to enable a correct irradiation of energy from the radiator element 2 and the electronic device 3. In other words, the various elements of the exchanger apparatus 1 according to the present invention are not physically in contact with one another.

The space or gap present between the various elements 2, 3 and 4 is filled with any material transparent to infrared rays, for example, a silicon-based gel can be advantageously used.

The temperature of the radiator element 2 is preferably comprised between 40° C. and 300° C.

The materials used for the radiator element 2 and the heat exchanger are preferably copper or aluminium.

Although the essential module that implements the invention is the one with three layers, shown in FIG. 2, wherein the electricity generating device 3 is “sandwiched” between the radiator element 2 and the exchanger 4 that delivers hot water as output, the invention can also be configured as a stack consisting of one or more modules formed by the following components positioned adjacent and in succession: a first exchanger 4, a first electronic device 3 for producing current, a radiator element 2, a second electronic device 3 and a second exchanger 4 (see FIG. 3).

If the stack continues, the second exchanger 4 of a module constitutes the first exchanger 4 of the next module, and so on; in other words, two modules share a same exchanger 4 which receives heat from a pair of photovoltaic panels 3 (or other electricity generating devices), which in turn absorbs energy from a respective radiator element 2.

In this manner, thermal dispersion is reduced to a minimum.

From the explanation set forth above, it may be understood that the invention overcomes all the limits of the prior art by providing an apparatus 1 that generates both electricity and hot water without using movable parts or any mechanical component.

What is claimed is:

1. An exchanger apparatus for supplying electricity and heat, comprising:
at least one radiator element which is able to irradiate electromagnetic energy in the infrared region as a function of an operating temperature thereof;
at least one electronic device which is designed to produce output electricity from the infrared energy irradiated by the radiator element, thereby dissipating heat; and
at least one heat exchanger designed to absorb the heat dissipated by said electronic device, thereby increasing the temperature of an output fluid.

2. The apparatus according to claim 1, wherein the radiator element is a heat exchanger through which a working fluid flows.

3. The apparatus according to claim 1, wherein said working fluid is chosen from among: diathermic oil, ethylene glycol or water.

4. The apparatus according to claim 1, wherein said output fluid is heated water.

5. The apparatus according to claim 1, wherein said electronic device is of the photovoltaic type and is designed to absorb electromagnetic radiation in the infrared field.

6. The apparatus according to claim 1, wherein said electrical device is a photovoltaic panel provided with an inverter to supply, as output, electricity to the network.

7. The apparatus according to claim 1, comprising at least one stack formed by the following components positioned adjacent and in succession: a first heat exchanger for absorbing heat, a first electronic device for producing electricity, a radiator element, a second electronic device and a second heat exchanger.
